(19) United States
(12) Patent Application Publication
(10) Pub. No.: US 2022/0074042 A1
(43) Pub. Date: Mar. 10, 2022

(54) APPARATUS AND METHOD FOR CONTROLLING COATING LAYER IN PVD PLATING PROCESS

(71) Applicant: POSCO, Pohang-si (KR)

(72) Inventors: Yong-Hwa JUNG, Gwangyang-si (KR); Kyung-Hoon NAM, Gwangyang-si (KR); Tae-Yeob KIM, Gwangyang-si (KR); Woo-Sung JUNG, Gwangyang-si (KR); Kyoung-Pil KO, Gwangyang-si (KR)

(21) Appl. No.: 17/414,753

(22) PCT Filed: Dec. 10, 2019
(86) PCT No.: PCT/KR2019/017361

§ 371 Date: Jun. 16, 2021

(30) Foreign Application Priority Data
Dec. 19, 2018 (KR) 10-2018-0165450

(51) Int. Cl. C23C 14/26; C23C 14/24; C23C 14/54

(52) U.S. Cl. CPC C23C 14/26; C23C 14/542; C23C 14/243

(57) ABSTRACT

Provided is an apparatus for controlling a coating layer in a physical vapor deposition (PVD) plating process that forms a coating layer on a steel sheet with metal vapor by PVD. The apparatus for controlling a coating layer comprises: a crucible into which a molten material is introduced; an electromagnetic induction coil disposed around the outer periphery of the crucible to heat the molten material introduced into the crucible and form a molten metal to generate metal vapor from the molten metal; a power supply unit for supplying an electric current to the electromagnetic induction coil; and a control unit for measuring the impedance of the electromagnetic induction coil and controlling the electric current supplied to the electromagnetic induction coil so that the impedance is kept constant according to the molten material which is introduced into the crucible at a constant feed rate.

### TECHNICAL FIELD

The present disclosure relates to an apparatus and a method for controlling a coating layer in physical vapor deposition (PVD) process, and more particularly, to an apparatus and a method for controlling an evaporation amount of a molten metal to control a thickness of a coating layer in a PVD plating process in which a steel sheet is coated using PVD.

### BACKGROUND ART

In a PVD plating process of coating a substrate moving in vacuum with metal vapor, a coating medium may be melted or heated by directing heating a crucible to generate a large amount of metal vapor (see European Patent Publication No. 1,785,010, for example), or a conductive medium may be heated by electromagnetic induction in a non-contact manner to generate metal vapor (see Korean Patent Publication No. 10-2007-0067097, for example). The two documents disclose a basic concept of PVD in which coating vapor is generated in vacuum to coat a substrate, but fail to disclose a technology to control a coating weight. That is, development of a unique coating weight control technology for PVD is required to manufacture plated products.

For coating a surface of a moving strip with metal vapor, hot-dip galvanizing and electroplating are mainly used in the related art. In the related art, a method of controlling a gap and a pressure of air knives (in the case of hot-dip galvanizing) or a method of controlling multiplication of current by time (in the case of electroplating) has been applied to control a coating weight. The above-mentioned technologies manufacture plated products in a manner of directly controlling a coating weight.

The inventor of the present disclosure developed a PVD plating apparatus for applying the above-mentioned PVD plating process to coating of a moving strip. A technology, capable of controlling a coating weight, is necessarily required to commercialize the PVD plating apparatus.

### DISCLOSURE

### Technical Problem

An aspect of the present disclosure is to provide an apparatus and a method for controlling an amount of metal vapor, generated in a PVD plating process, to control a coating layer of a steel sheet.

### Technical Solution

According to an aspect of the present disclosure, an apparatus for controlling a coating layer in a physical vapor deposition (PVD) plating process, in which a steel sheet is subjected to PVD with metal vapor to form a coating layer, is provided. The apparatus includes: a crucible into which a molten material is introduced; an electromagnetic induction coil disposed around an external periphery of the crucible to heat the molten material introduced to the crucible and to form a molten metal to generate metal vapor from the molten metal; a power supply unit configured to supply current to the electromagnetic induction coil; and a control unit configured to measure impedance of the electromagnetic induction coil and to control the current, supplied to the electromagnetic induction coil, such that the impedance is maintained to be constant, depending on the molten material introduced to the crucible.

In an example embodiment, the control unit may measure a resonant frequency of the electromagnetic induction coil to obtain the impedance of the electromagnetic induction coil.

In an example embodiment, the control unit may control the current, supplied to the electromagnetic induction coil, such that a heating value generated by the electromagnetic induction coil is set to be constant.

In an example embodiment, the heating value may correspond to an amount of power of the electromagnetic induction coil, and the control unit may control the current, supplied to the electromagnetic induction coil, such that the amount of the power of the electromagnetic induction coil is set to be constant.

According to another aspect of the present disclosure, a method for controlling a coating layer in a physical vapor deposition (PVD) plating process, in which a steel sheet is subjected to PVD with metal vapor to form a coating layer, is provided. The method includes: introducing a molten material into a crucible; heating the molten material, introduced to the crucible, with an electromagnetic induction coil, disposed around an external periphery of the crucible, and forming a molten material to generate metal vapor; measuring impedance of the electromagnetic induction coil; and controlling current, supplied to the electromagnetic induction coil, such that the impedance of the electromagnetic induction coil is maintained to be constant, depending on the molten material introduced to the crucible at a constant feed rate.

In an example embodiment, the measuring of impedance of the electromagnetic induction coil may include measuring a resonant frequency of the electromagnetic induction coil to obtain the impedance of the electromagnetic induction coil.

In an example embodiment, the controlling of the current supplied to the electromagnetic induction coil may include controlling the current, supplied to the electromagnetic induction coil, such that a heating value generated by the electromagnetic induction coil is set to be constant.

In an example embodiment, the heating value corresponds to an amount of power of the electromagnetic induction coil, and the controlling of the current supplied to the electromagnetic induction coil may include controlling the current, supplied to the electromagnetic induction coil, such that the amount of the power of the electromagnetic induction coil is set to be constant.

The technical solution clause does not necessarily describe all necessary features of the present disclosure. The present disclosure may also be a sub-combination of the features described above.

### Advantageous Effects

As set forth above, the amount of metal vapor, generated in a PVD plating process, may be controlled to be constant. Thus, a coating layer formed on a steel sheet may be controlled to be constant.

### DESCRIPTION OF DRAWINGS

FIG. 1 is a schematic diagram of an apparatus for controlling a coating layer in a PVD plating process according to an example embodiment of the present disclosure.

FIG. 2 is a schematic flowchart illustrating a method for controlling a coating layer in a PVD plating process according to an example embodiment of the present disclosure.

### BEST MODE FOR INVENTION

Hereinafter, an apparatus and a method for controlling a coating layer in a PVD plating process according to example embodiments of the present disclosure will be described with reference to accompanying drawings.

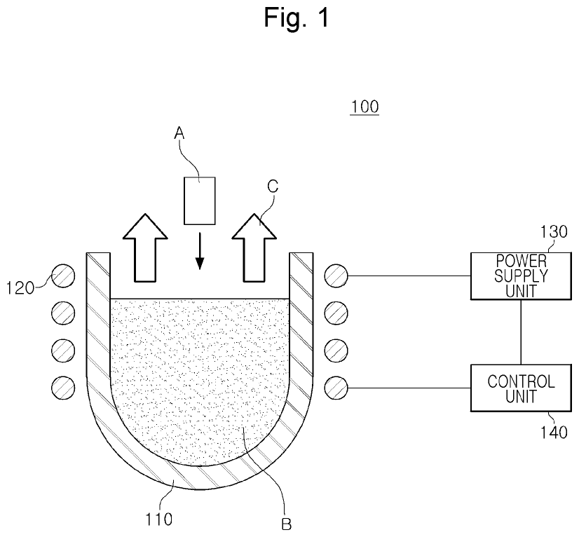

FIG. 1 is a block diagram of an apparatus 100 for controlling a coating layer in a PVD plating process according to an example embodiment of the present disclosure. As illustrated in FIG. 1, the apparatus 100 may be used in a PVD plating process in which a strip is subjected to physical vapor deposition (PVD) with metal vapor to form a coating layer. The apparatus 100 may include a crucible 110 into which a molten material ‘A’ is introduced, an electromagnetic induction coil 120 disposed around an external periphery of the crucible 110 to heat the molten material ‘A’ introduced to the crucible 110 and to form a molten metal ‘B’ to generate metal vapor ‘C’ from the molten metal ‘B,’ a power supply unit 130 supplying current to the electromagnetic induction coil 120, and a control unit 140 controlling the current supplied to the electromagnetic induction coil 120.

In the PVD plating process, a plating medium of a predetermined component (for example, the molten material ‘A’) may be introduced to the crucible 110 in which the electromagnetic induction coil 120 is disposed around the external periphery, and current may be supplied to the electromagnetic induction coil 120 to form the molten metal ‘B’ in the crucible 110. Thus, the metal vapor ‘C’ may be generated, and then deposited on the strip to form a coating layer. For this reason, the coating layer may be controlled by controlling the amount of the metal vapor ‘C.’

The present disclosure proposes a method of controlling a coating layer. According to the method, the same amount of molten material ‘A’ as the metal vapor ‘C’ to be generated may be introduced to the crucible 110 to control the amount of the metal vapor ‘C’ and then the amount of the molten metal ‘B,’ for example, the volume of the molten metal ‘B’ may be maintained to be constant, so that the coating layer may be controlled.

To this end, the control unit 140 may measure impedance of the electromagnetic induction coil 120 and may control the current, supplied to the electromagnetic induction coil 120, such that the impedance may be maintained to be constant. For example, the control unit 140 may control parameters of the current, supplied to the electromagnetic induction coil 120, including the magnitude of the current, or the like. The impedance of the electromagnetic induction coil 120 may vary depending on a change in volume of the molten metal ‘B’ in the crucible 110. Accordingly, when the current supplied to the electromagnetic induction coil 120, for example, the magnitude of the current, or the like, is controlled such that the impedance of the electromagnetic induction coil 120 is set to be constant depending on the molten material ‘A’ introduced to the crucible 110 at a constant feed rate, the volume of the molten metal ‘B’ may be controlled to be constant. Results of simulation for the amount of the molten metal ‘B’ and the impedance of the electromagnetic induction coil 120 are listed in Table 1 below.

TABLE 1

Amount of Molten Steel(kg)

| | 1 | 1.5 | 2 | 2.5 | 3 | 3.5 |
|---|---|---|---|---|---|---|
| Impedance | 4.7 | 4.35 | 4.18 | 4.12 | 4.06 | 4 |

Accordingly, it is confirmed that the larger the volume of the molten metal ‘B,’ the lower the impedance of the electromagnetic induction coil 120. The control unit 140 may measure a resonant frequency of the electromagnetic induction coil 120 to obtain the impedance of the electromagnetic induction coil 120. A relationship between the resonant frequency and the impedance of the electromagnetic induction coil is represented by the following equation 1.

$$f = \frac{1}{2 π \sqrt{LC}} \qquad Equation 1$$

where f is the resonant frequency of the electromagnetic induction coil 120, L is the impedance of the electromagnetic induction coil 120, and C is capacitance in a PVD plating apparatus and is a fixed value.

Accordingly, the coating layer may be controlled by measuring the resonant frequency and controlling power, supplied to the electromagnetic induction coil 120, such that the resonant frequency is set to be constant.

The feed rate of the molten material ‘A’ fed into the crucible 110 and a generation rate of the metal vapor ‘C’ should match each other. For example, the amount of the molten material ‘A’ fed per unit time and the amount of the metal vapor ‘C’ generated per unit time should match each other. To this end, the metal vapor ‘C’ may be maintained to be constant, depending on the introduced molten material ‘A’ by maintaining a heating value of the electromagnetic induction coil 120 to be constant depending on the molten material ‘A’ introduced to the crucible 110 at the constant feed rate, in addition to by maintaining the volume of the molten metal ‘B’ to be constant depending on the molten material ‘A’ introduced to the crucible 110 at the constant feed rate.

The heating value may correspond to energy required for maintenance of the temperature of the molten metal ‘B,’ an increase in the temperature of the fed molten material ‘A,’ and evaporation heat. The heating value may correspond to the amount of power of the electromagnetic induction coil 120, and the controller 140 may control the current supplied to the electromagnetic induction coil 120 such that the amount of power of the electromagnetic induction coil 120 is set to be constant.

As described above, in the apparatus for controlling a coating layer in the PVD plating process according to an example embodiment, impedance (for example, a resonant frequency) and a heating value (for example, the amount of power) may be controlled to be constant to correspond to a molten material fed at a constant feed rate, so that a heating value of metal vapor may be controlled to be constant. As a result, a constant coating layer may be formed.

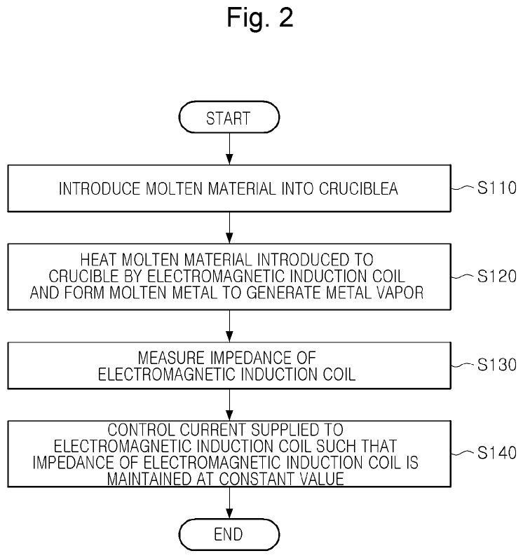

Next, a method for controlling a coating layer in a PVD plating process according to an example embodiment of the present disclosure will be described with reference to FIG. 2. FIG. 2 is a schematic flowchart illustrating a method 200 for controlling a coating layer in a PVD plating process according to an example embodiment. The method 200 for controlling a coating layer according to an example embodiment may be used in a PVD plating process in which a strip is subjected to physical vapor deposition with metal vapor to form a coating layer.

The method 200 may start with operation S210 in which a molten material is introduced to a crucible. In operation S220, the molten material in the crucible may be heated with an electromagnetic induction coil disposed around an external periphery of the crucible, and then a molten metal may be formed to generate metal vapor. In operation S230, impedance of the electromagnetic induction coil may be measured. In operation S240, current supplied to the electromagnetic induction coil may be controlled such that the impedance of the electromagnetic induction coil is maintained to be constant according to the molten material introduced to the crucible at a constant feed rate. A procedure and a principle of each operation of the method 200 are substantially the same as those of each component of the above-described apparatus 100, and thus, detailed descriptions thereof will be omitted.

In operation S230 in which the impedance of the electromagnetic induction coil is measured, a resonant frequency of the electromagnetic induction coil may be measured to obtain the impedance of the electromagnetic induction coil. As described above, the impedance may be calculated from the resonant frequency (for example, using Equation 1). Therefore, when the current of the electromagnetic induction coil is controlled such that the resonant frequency is set to be constant, the impedance may be set to be constant.

In an example embodiment, in operation S240 in which the current supplied to the electromagnetic induction coil is controlled, the current supplied to the electromagnetic induction coil may be controlled such that a heating value generated by the electromagnetic induction coil is set to be constant, in addition to controlling the current supplied to the electromagnetic induction coil such that the impedance of the electromagnetic induction coil is maintained to be constant, depending on the molten material introduced to the crucible at a constant feed rate.

In this case, the heating value may correspond to the amount of power of the electromagnetic induction coil. Accordingly, in operation S240 in which the current supplied to the electromagnetic induction coil is controlled, the current supplied to the electromagnetic induction coil may be controlled such that the amount of power of the electromagnetic induction coil is set to be constant, and thus, the heating value may be set to be constant.

As described above, in the method for controlling a coating layer in a PVD plating process according to an example embodiment, similarly to the above-described method for controlling a plating layer, impedance (for example, a resonant frequency) and a heating value (for example, the amount of power) may be controlled to be constant to correspond to a molten material fed at a constant feed rate, so that a heating value of metal vapor may be controlled to be constant. As a result, a constant coating layer may be formed.

While examples embodiments in the present disclosure have been described in detail, however, claims of the present disclosure are not limited thereto, and it will be apparent to those skilled in the art that various modifications and changes may be made without departing from the technological concepts of the present disclosure described in the claims.

### DESCRIPTION OF REFERENCE NUMERALS

100 APPARATUS FOR CONTROLLING COATING LAYER
110 CRUCIBLE
120 ELECTROMAGNETIC INDUCTION COIL
130 POWER SUPPLY UNIT
140 CONTROL UNIT
A MOLTEN MATERIAL
B MOLTEN STEEL
C METAL VAPOR

1. An apparatus for controlling a coating layer in a physical vapor deposition (PVD) plating process in which a steel sheet is subjected to PVD with metal vapor to form a coating layer, the apparatus comprising:
a crucible into which a molten material is introduced;
an electromagnetic induction coil disposed around an external periphery of the crucible to heat the molten material introduced to the crucible and to form a molten metal to generate metal vapor from the molten metal;
a power supply unit configured to supply current to the electromagnetic induction coil; and
a control unit configured to measure impedance of the electromagnetic induction coil and to control the current, supplied to the electromagnetic induction coil, such that the impedance is maintained to be constant, depending on the molten material introduced to the crucible.

2. The apparatus of claim 1, wherein the control unit measures a resonant frequency of the electromagnetic induction coil to obtain the impedance of the electromagnetic induction coil.

3. The apparatus of claim 1, wherein the control unit controls the current, supplied to the electromagnetic induction coil, such that a heating value generated by the electromagnetic induction coil is set to be constant.

4. The apparatus of claim 3, wherein the heating value corresponds to an amount of power of the electromagnetic induction coil, and the control unit controls the current, supplied to the electromagnetic induction coil, such that the amount of the power of the electromagnetic induction coil is set to be constant.

5. A method for controlling a coating layer in a physical vapor deposition (PVD) plating process in which a steel sheet is subjected to PVD with metal vapor to form a coating layer, the method comprising:
introducing a molten material into a crucible;
heating the molten material, introduced to the crucible, with an electromagnetic induction coil, disposed around an external periphery of the crucible, and forming a molten material to generate metal vapor;
measuring impedance of the electromagnetic induction coil; and
controlling current, supplied to the electromagnetic induction coil, such that the impedance of the electromagnetic induction coil is maintained to be constant, depending on the molten material introduced to the crucible at a constant feed rate.

6. The method of claim 5, wherein the measuring of impedance of the electromagnetic induction coil includes measuring a resonant frequency of the electromagnetic induction coil to obtain the impedance of the electromagnetic induction coil.

7. The method of claim 5, wherein the controlling of the current supplied to the electromagnetic induction coil includes controlling the current, supplied to the electromagnetic induction coil, such that a heating value generated by the electromagnetic induction coil is set to be constant.

8. The method of claim 7, wherein the heating value corresponds to an amount of power of the electromagnetic induction coil, and
wherein the controlling of the current supplied to the electromagnetic induction coil includes controlling the current, supplied to the electromagnetic induction coil, such that the amount of the power of the electromagnetic induction coil is set to be constant.
